(19) United States
(12) Patent Application Publication
(10) Pub. No.: US 2023/0418604 A1
(43) Pub. Date: Dec. 28, 2023

(54) RECONFIGURABLE VECTOR PROCESSING IN A MEMORY

(71) Applicant: Intel Corporation, Santa Clara, CA (US)

(72) Inventors: Abhishek Anil Sharma, Portland, OR (US); Pushkar Ranade, San Jose, CA (US); Wilfred Gomes, Portland, OR (US); Sagar Suthram, Portland, OR (US)

(21) Appl. No.: 17/850,044

(22) Filed: Jun. 27, 2022

(51) Int. Cl. G06F 9/30; G06F 9/445; G06F 9/50

(52) U.S. Cl. CPC G06F 9/30036; G06F 9/5016; G06F 9/44505

(57) ABSTRACT

In one embodiment, a memory includes a die having: one or more memory layers having a plurality of banks to store data; and at least one other layer comprising at least one reconfigurable vector processor, the at least one reconfigurable vector processor to perform a vector computation on input vector data obtained from at least one bank of the plurality of banks and provide processed vector data to the at least one bank. Other embodiments are described and claimed.

### BACKGROUND

A recent trend in memory technology is the inclusion of execution circuitry within a memory itself. With this inclusion, certain basic operations can be performed directly within the memory. However the available operations are limited, and undesired latency and complexity occurs, as typically a full path from a processor that initiates the operation to the memory and back to the processor occurs.

### BRIEF DESCRIPTION OF THE DRAWINGS

FIG. 1 is a block diagram of a package having memory tightly coupled with processing circuitry in accordance with an embodiment.

FIG. 2 is a cross sectional view of a package in accordance with an embodiment.

FIG. 3 is a block diagram of a scalable integrated circuit package in accordance with an embodiment.

FIG. 4 is a block diagram of a scalable package in accordance with another embodiment.

FIG. 5 is a block diagram of a portion of a system in accordance with an embodiment.

FIG. 6 is a block diagram of a memory device in accordance with an embodiment.

FIG. 7 illustrates schematic diagrams of possible configurations of a reconfigurable vector processing circuit in accordance with an embodiment.

FIG. 8 is a flow diagram of a method in accordance with an embodiment.

FIG. 9 is a block diagram of an example system with which embodiments can be used.

FIG. 10 is a block diagram of a system in accordance with another embodiment.

FIG. 11 is a block diagram of a system in accordance with another embodiment.

FIG. 12 is a block diagram illustrating an IP core development system used to manufacture an integrated circuit to perform operations according to an embodiment.

### DETAILED DESCRIPTION

In various embodiments, a memory such as a dynamic random access memory (DRAM) may include processing circuitry in close relation to memory circuitry of the DRAM to perform certain processing operations such as arithmetic operations, reducing latency and complexity.

More particularly with embodiments herein, a DRAM may include one or more reconfigurable vector processors that can perform vector operations locally within the DRAM itself. And with embodiments, results of such vector operations can be locally stored within the DRAM without result data being sent back to a processor such as a central processing unit (CPU), further reducing latency. Instead with an embodiment, the memory can send status information in the form of a status message to the processor to inform the processor as to completion of a vector operation.

In some embodiments, the DRAM may have a custom-implemented arrangement to more efficiently store and access vector data (in row and column arrangement). With this arrangement certain banks can be configured store row data in a first orientation to enable efficient access, and other banks can store column data in this first orientation to enable efficient access. In contrast, typical memory structures include a single configuration such that only row data is stored in this first orientation.

The memory may further store configuration information to enable dynamic configuration and reconfiguration of a reconfigurable vector processor. To this end, this configuration information may be sent via bitlines to the reconfigurable vector processor, which may include switch circuitry to cause a given configuration of the reconfigurable vector processor.

In various embodiments, an integrated circuit (IC) package may include multiple dies in stacked relation. More particularly in embodiments, at least one compute die may be adapted on a memory die in a manner to provide fine-grained memory access by way of localized dense connectivity between compute elements of the compute die and localized banks (or other local portions) of the memory die. This close physical coupling of compute elements to corresponding local portions of the memory die enables the compute elements to locally access local memory portions, in contrast to a centralized memory access system that is conventionally implemented via a centralized memory controller.

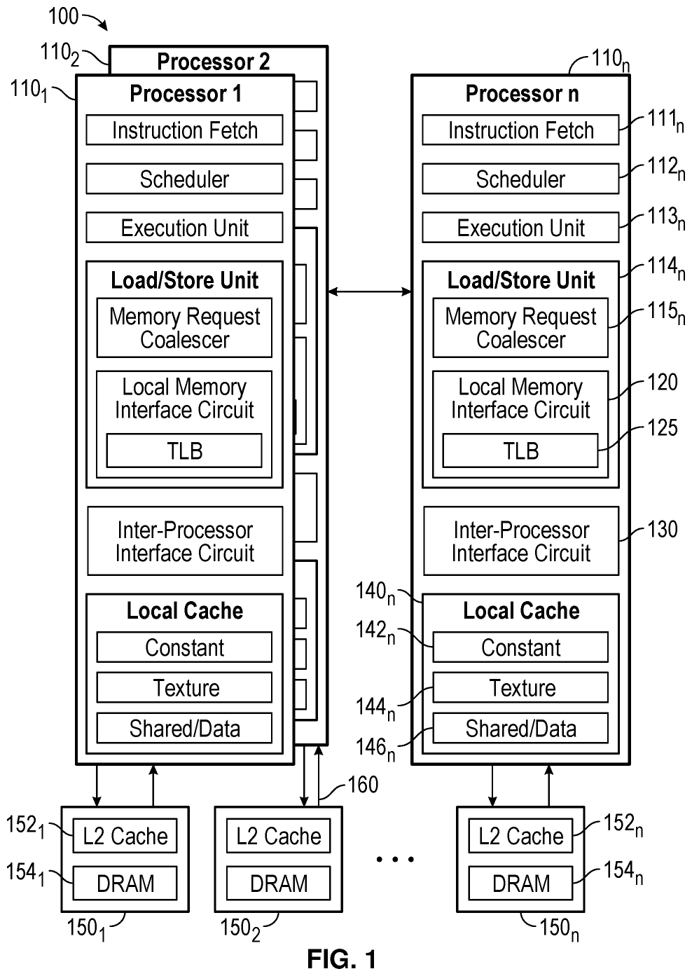

Referring now to FIG. 1, shown is a block diagram of a package having memory tightly coupled with processing circuitry in accordance with an embodiment. As shown in FIG. 1, package 100 includes a plurality of processors 110₁-110ₙ. In the embodiment shown, processors 110 are implemented as streaming processors. However embodiments are not limited in this regard, and in other cases the processors may be implemented as general-purpose processing cores, accelerators such as specialized or fixed function units or so forth. As used herein, the term “core” refers generally to any type of processing circuitry that is configured to execute instructions, tasks and/or workloads, namely to process data.

In the embodiment of FIG. 1, processors 110 each individually couple directly to corresponding portions of a memory 150, namely memory portions 150₁-150ₙ. As such, each processor 110 directly couples to a corresponding local portion of memory 150 without a centralized interconnection network therebetween. In one or more embodiments described herein, this direct coupling may be implemented by stacking multiple die within package 100. For example, processors 110 may be implemented on a first die and memory 150 may be implemented on at least one other die, where these dies may be stacked on top of each other, as will be described more fully below. By “direct coupling” it is meant that a processor (core) is physically in close relation to a local portion of memory in a non-centralized arrangement so that the processor (core) has access only to a given local memory portion and without communicating through a memory controller or other centralized controller.

As seen, each instantiation of processor 110 may directly couple to a corresponding portion of memory 150 via interconnects 160. Although different physical interconnect structures are possible, in many cases, interconnects 160 may be implemented by one or more of conductive pads, bumps or so forth. Each processor 110 may include through silicon vias (TSVs) that directly couple to TSVs of a corresponding local portion of memory 150. In such arrangements, interconnects 160 may be implemented as bumps or hybrid bonding or other bumpless technique.

Memory 150 may, in one or more embodiments, include a level 2 (L2) cache 152 and a dynamic random access memory (DRAM) 154. As illustrated, each portion of memory 150 may include one or more banks or other portions of DRAM 154 associated with a corresponding processor 110. In one embodiment, each DRAM portion 154 may have a width of at least 1024 words. Of course other widths are possible. Also while a memory hierarchy including both an L2 cache and DRAM is shown in FIG. 1, it is possible for an implementation to provide only DRAM 154 without presence of an L2 cache (at least within memory 150). This is so, as DRAM 154 may be configured to operate as a cache, as it may provide both spatial and temporal locality for data to be used by its corresponding processor 110. This is particularly so when package 100 is included in a system having a system memory (e.g., implemented as dual-inline memory modules (DIMMs) or other volatile or non-volatile memory).

In addition, memory 150 may include reconfigurable processing circuitry (including at least vector processing circuitry) to enable certain processing operations to be performed directly within memory 150, without communication of intermediate data and/or result data back to processors 110.

With embodiments, package 100 may be implemented within a given system implementation, which may be any type of computing device that is a shared DRAM-less system, by using memory 150 as a flat memory hierarchy. Such implementations may be possible, given the localized dense connectivity between corresponding processors 110 and memory portions 150 that may provide for dense local access on a fine-grained basis. In this way, such implementations may rely on physically close connections to localized memories 150, rather than a centralized access mechanism, such as a centralized memory controller of a processor.

Further, direct connection occurs via interconnects 160 without a centralized interconnection network.

Still with reference to FIG. 1, each processor 110 may include an instruction fetch circuit 111 that is configured to fetch instructions and provide them to a scheduler 112. Scheduler 112 may be configured to schedule instructions for execution on one or more execution circuits 113, which may include arithmetic logic units (ALUs) and so forth to perform operations on data in response to decoded instructions, which may be decoded in an instruction decoder, either included within processor 110 or elsewhere within an SoC or another processor.

As further shown in FIG. 1, processor 110 also may include a load/store unit 114 that includes a memory request coalescer 115. Load/store unit 114 may handle interaction with corresponding local memory 150. To this end, each processor 110 further may include a local memory interface circuit 120 that includes a translation lookaside buffer (TLB) 125. In other implementations local memory interface circuit 120 may be separate from load/store unit 114.

In embodiments herein, TLB 125 may be configured to operate on only a portion of an address space, namely that portion associated with its corresponding local memory 150. To this end, TLB 125 may include data structures that are configured for only such portion of an entire address space. For example, assume an entire address space is 2⁶⁴ bytes corresponding to a 64-bit addressing scheme. Depending upon a particular implementation and sizing of an overall memory and individual memory portions, TLB 125 may operate on somewhere between approximately 10 and 50 bits.

Still with reference to FIG. 1, each processor 110 further includes a local cache 140 which may be implemented as a level 1 (L1) cache. Various data that may be frequently and/or recently used within processor 110 may be stored within local cache 140. In the illustration of FIG. 1, exemplary specific data types that may be stored within local cache 140 include constant data 142, texture data 144, and shared/data 146. Note that such data types may be especially appropriate when processor 110 is implemented as a graphics processing unit (GPU). Of course other data types may be more appropriate for other processing circuits, such as general-purpose processing cores or other specialized processing units.

Still referring to FIG. 1, each processor 110 may further include an inter-processor interface circuit 130. Inter-processor interface circuit 130 may be configured to provide communication between a given processor 110 and its neighboring processors, e.g., a nearest neighbor on either side of processor 130. Although embodiments are not limited in this regard, in one or more embodiments inter-processor interface circuit 130 may implement a message passing interface (MPI) to provide communication between neighboring processors. While shown at this high level in the embodiment of FIG. 1, many variations and alternatives are possible. For example, more dies may be present in a given package, including multiple memory dies that form one or more levels of a memory hierarchy and additional compute, interface, and/or controller dies.

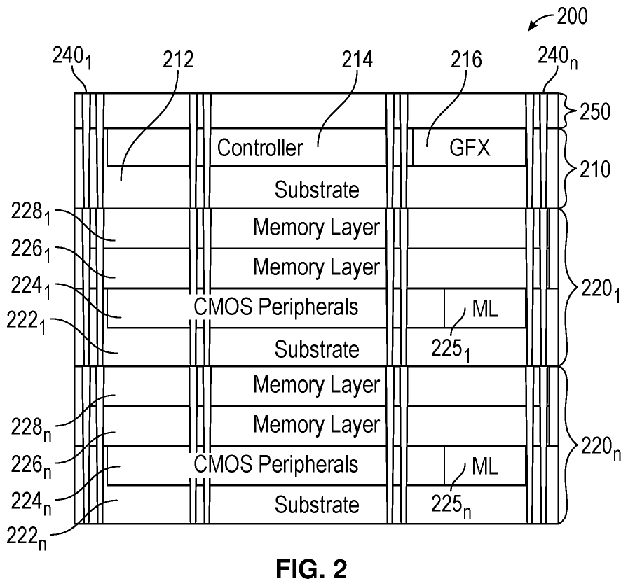

Referring now to FIG. 2, shown is a cross sectional view of a package in accordance with an embodiment. As shown in FIG. 2, package 200 is a multi-die package including a set of stacked die, namely a first die 210, which may be a compute die and multiple memory die 220₁ and 220₂. With this stacked arrangement, compute die 210 may be stacked above memory die 220 such that localized dense connectivity is realized between corresponding portions of memory die 220 and compute die 210. As further illustrated, a package substrate 250 may be present onto which the stacked dies may be adapted. In an embodiment, compute die 210 may be adapted at the top of the stack to improve cooling.

As further illustrated in FIG. 2, physical interconnection between circuitry present on the different die may be realized by TSVs 240₁-240ₙ (each of which may be formed of independent TSVs of each die). In this way, individual memory cells of a given portion may be directly coupled to circuitry present within compute die 210. Note further that in FIG. 2, in the cross-sectional view, only circuitry of a single processing circuit and a single memory portion is illustrated. As shown, with respect to compute die 210, a substrate 212 is provided in which controller circuitry 214 and graphics circuitry 216 is present.

With reference to memory die 220, a substrate 222 is present in which complementary metal oxide semiconductor (CMOS) peripheral circuitry 224 may be implemented, along with memory logic (ML) 225, which may include localized memory controller circuitry and/or cache controller circuitry. In certain implementations, CMOS peripheral circuitry 224 may include reconfigurable vector processing circuitry as described herein. In some cases CMOS peripheral circuitry 224 may further include additional processing circuitry such as encryption/decryption circuitry or so forth. As further illustrated, each memory die 220 may include multiple layers of memory circuitry. In one or more embodiments, there may be a minimal distance between CMOS peripheral circuitry 224 and logic circuitry (e.g., controller circuitry 214 and graphics circuitry 216) of compute die 210, such as less than one micron.

As shown, memory die 220 may include memory layers 226, 228. While shown with two layers in this example, understand that more layers may be present in other implementations. In each layer, a plurality of bit cells may be provided, such that each portion of memory die 220 provides a locally dense full width storage capacity for a corresponding locally coupled processor. Note that memory die 220 may be implemented in a manner in which the memory circuitry of layers 226, 228 may be implemented with backend of line (BEOL) techniques. While shown at this high level in FIG. 2, many variations and alternatives are possible.

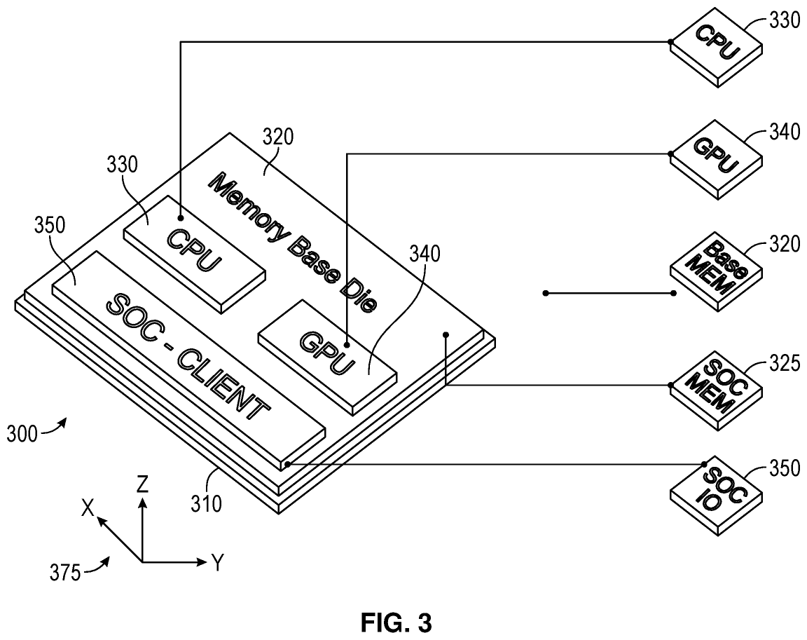

Referring now to FIG. 3, shown is a block diagram of a scalable integrated circuit (IC) package in accordance with an embodiment. As shown in FIG. 3, package 300 is shown in an opened state; that is, without an actual package adapted about the various circuitry present. In the high level shown in FIG. 3, package 300 is implemented as a multi-die package having a plurality of dies adapted on a substrate 310. Substrate 310 may be a glass or sapphire substrate (to support wide bandwidth with low parasitics) and may, in some cases, include interconnect circuitry to couple various dies within package 300 and to further couple to components external to package 300.

In the illustration of FIG. 3, a memory die 320 is adapted on substrate 310. In embodiments herein, memory die 320 may be a DRAM that includes reconfigurable vector processing circuitry arranged according to an embodiment herein. Further each of the local portions may directly and locally couple with a corresponding local processor such as a general-purpose or specialized processing core with which it is associated (such as described above with regard to FIGS. 1 and 2).

In one or more embodiments, each local portion may be configured as an independent memory channel, e.g., as a double data rate (DDR) memory channel. In some embodiments, these DDR channels of memory die 320 may be an embedded DRAM (eDRAM) that replaces a conventional package-external DRAM, e.g., formed of conventional dual inline memory modules (DIMMs). While not shown in the high level view of FIG. 3, memory die 320 may further include an interconnection network, such as at least a portion of a global interconnect network that can be used to couple together different dies that may be adapted above memory die 320.

As further shown in FIG. 3, multiple dies may be adapted above memory die 320. As shown, a central processing unit (CPU) die 330, a graphics (graphics processing unit (GPU)) die 340, and a SoC die 350 all may be adapted on memory die 320. FIG. 3 further shows in inset these disaggregated dies, prior to adaptation in package 300. CPU die 330 and GPU die 340 may include a plurality of general-purpose processing cores and graphics processing cores, respectively. In some use cases, instead of a graphics die, another type of specialized processing unit (generically referred to as an “XPU”) may be present. Regardless of the specific compute dies present, each of these cores may locally and directly couple to a corresponding portion of the DRAM of memory die 320, e.g., by way of TSVs, as discussed above. In addition, CPU die 330 and GPU die 340 may communicate via interconnect circuitry (e.g., a stitching fabric or other interconnection network) present on or within memory die 320. Similarly, additional circuitry of an SoC, including interface circuitry to interface with other ICs or other components of a system may occur via circuitry of SoC die 350.

While shown with a single CPU die and single GPU die, in other implementations multiple ones of one or both of CPU and GPU dies may be present. More generally, different numbers of CPU and XPU dies (or other heterogenous dies) may be present in a given implementation.

Package 300 may be appropriate for use in relatively small computing devices such as smartphones, tablets, embedded systems and so forth. As discussed, with the ability to provide scalability by adding multiple additional processing dies, packages in accordance with embodiments can be used in these and larger more complex systems.

Further while shown with this particular implementation in FIG. 3, in some cases one or more additional memory dies configured with local DRAM portions similar to memory die 320 may be present. It is also possible for one or more of these additional memory dies to be implemented as conventional DRAM, to avoid the need for package-external DRAM.

Thus as shown in the inset of FIG. 3, an additional memory die 325 may take the form of a conventional DRAM. In such an implementation, memory die 320 may be managed to operate as at least one level of a cache memory hierarchy, while memory die 325 acts as a system memory, providing higher storage capacity. Depending on implementation, memory die 320 may be adapted on memory die 325, which is thus sandwiched between memory die 320 and substrate 310. While shown at this high level in the embodiment of FIG. 3, many variations and alternatives are possible. For example, as shown with reference to X-Y-Z coordinate system 375, package 300 can be extended in each of 3 dimensions to accommodate larger die footprints, as well as to provide additional dies in a stacked arrangement.

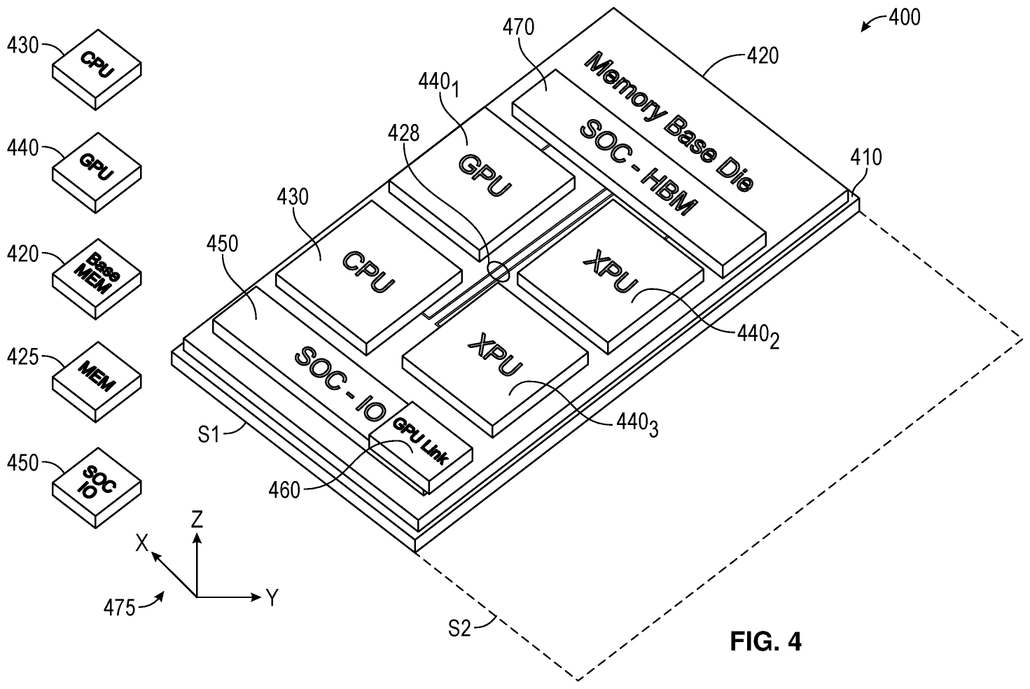

Additional dies may be adapted within a package in accordance with other embodiments. Referring now to FIG. 4, shown is a block diagram of a package in accordance with another embodiment. In FIG. 4, multi-die package 400 includes a similar stacked arrangement of dies, including substrate 410, memory die 420 and additional die adapted on memory die 420. Since similar dies may be present in the embodiment of FIG. 4 as in the FIG. 3 embodiment, the same numbering scheme is used (of the “400” series, instead of the “300” series of FIG. 3).

However in the embodiment of FIG. 4, package 400 includes additional dies adapted on memory die 420. As shown, in addition to CPU die 430, three additional dies 440₁₋₃ are present. More specifically, die 440₁ is a GPU die and dies 440₂₋₃ are XPU dies. As with the above discussion, each die 440 may locally couple to corresponding local portions of DRAM of a memory die 420 by way of TSVs. In this way, individual processing cores within each of dies 440 may be locally coupled with corresponding local memory. And, as shown in FIG. 4, memory die 420 may include an interconnection network 428 (or other switching or stitching fabric) that may be used to couple together two or more of the dies adapted on memory die 420. Note that interconnect network 428 may be included on and/or within memory die 420.

Still with reference to FIG. 4, additional SoC dies may be present, including an SoC die 470 which may include memory controller circuitry that can interface with a high bandwidth memory (HBM) that is external to package 400. In addition, multiple interface die, including an SoC interface die 450 and a graphics interface die 460, may be present, which may provide interconnection between various dies within package 400 and external components.

As with the above discussion of FIG. 3, one or more additional memory die (e.g., memory die 425 shown in the inset) may be stacked within the package arrangement. Such additional memory die may include one or more dies including DRAM configured with local portions and interconnection circuitry as with memory die 420, and/or conventional DRAM. In this way, package 400 may be used in larger, more complex systems, including high end client computing devices, server computers, or other data center equipment.

Still further, understand that package 400 may represent, with respect to memory die 420, a single stamping (S1) or base die arrangement of memory circuitry including multiple local memory portions and corresponding interconnect circuitry. This single stamping may be one of multiple such stampings (representative additional stamping S2 is shown in dashed form in FIG. 4) that can be fabricated on a semiconductor wafer, which is then diced into multiple iterations of this base memory die, where each die has the same stamping, namely, the same circuitry.

It is also possible to provide a multi-die package that is the size of an entire semiconductor wafer (or at least substantially wafer-sized) (e.g., a typical 300 millimeter (mm) semiconductor wafer). With such arrangement, a single package may include multiple stampings of a base memory die (or multiple such dies). In turn, each of the stampings may have adapted thereon multiple processing dies and associated circuitry. As an example, assume that base memory die 420 of FIG. 4 has first dimensions to represent a single stamping. Extending this stamping in the x and y directions for an entire wafer size may enable a given plurality of stampings to be present. In this way, a package having a substantially wafer-sized memory base layer may include a given number of iterations of the die configuration shown in FIG. 4. Thus with embodiments, scalability may be realized in all of x, y, and z dimensions of X-Y-Z coordinate system 475.

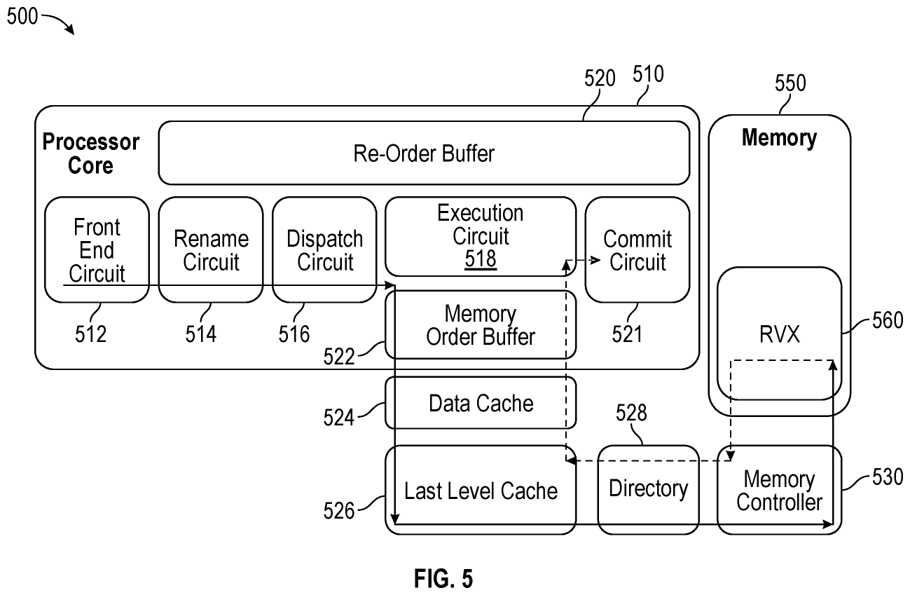

As discussed above, reconfigurable vector processing circuitry may be implemented within a memory device itself. Referring now to FIG. 5, shown is a block diagram of a portion of a system in accordance with an embodiment. As shown in FIG. 5, system 500 may be any type of computing device having a processor 510 and a memory 550, e.g., implemented as a DRAM. More specifically, the portion of processor 510 that is illustrated includes a processor core that shows, at a high level, a processor pipeline having a front end circuit 512 that may be configured to obtain and decode incoming instructions, e.g., into one or more micro-operations (pops). In turn, these pops are provided to a rename circuit 514, which may rename incoming operand identifiers, e.g., architectural registers, onto physical registers. A dispatch circuit 516 may dispatch the pops for execution in an execution circuit 518. Execution circuit 518 may include various arithmetic logic units (including scalar and vector execution units) to perform various operations including scalar and vector-based operations. At least some source operands for such execution may be obtained using a reorder buffer 520. In turn, instructions may be provided to a commit circuit 521 for retirement, and to a memory order buffer 522 for interfacing with a memory hierarchy.

Still with reference to FIG. 5, core 510 may interface with memory 550 via a path including memory order buffer 522, a data cache 524 (which in an embodiment may be a level 1 (L1) cache) and a last level cache 526. Last level cache 526 couples to a directory 528 that in turn is coupled to a memory controller 530. Memory controller 530 may be an integrated memory controller present within the processor.

Memory controller 530 acts as an interface with memory 550. As will be described herein, memory 550 may include one or more reconfigurable vector execution circuits (RVX) 560 that may be used to perform in-memory vector processing to improve performance, reduce power consumption and latencies. For example, in some cases instead of performing vector processing within execution circuit 518, which may first require traversing to memory 550 to obtain data, then processing that data in execution circuit 518, and then passing the processed data (e.g., result data) back to memory 550, vector processing may be performed directly within RVX 560 within memory 550, such that this vector processing can be performed without source and result data ever leaving memory 550.

Thus as further shown in FIG. 5, certain instructions and configuration information may be provided from processor core 510 to memory 550 (shown at solid line 570). The configuration information may be used to cause a configuration of one or more reconfigurable vector processors within memory 550. Further assume that the instruction flow includes one or more so-called RVX (in-memory vector processing) instructions of an instruction set architecture (ISA). As an example, a given RVX instruction may provide an indication of a type of vector operation to be performed and an identification of source operands (which may be vector width operands) and a destination operand. In one or more embodiments, RVX configuration information may precede an instruction stream of RVX instructions, such that first the RVX is configured and then performs a plurality of vector operations in response to the RVX instructions. Understand that the location of both the source and destination operands may be internal to memory 550, thus reducing latency of obtaining data, performing the vector operation(s) and storing result data.

As further shown in FIG. 5, dashed line 580 shows a flow of RVX status information back to core 510. This status information may indicate a status of RVX instruction execution within memory 550 to indicate whether a given instruction has successfully executed, among other status information. Understand while shown at this high level in the embodiment of FIG. 5, many variations and alternatives are possible.

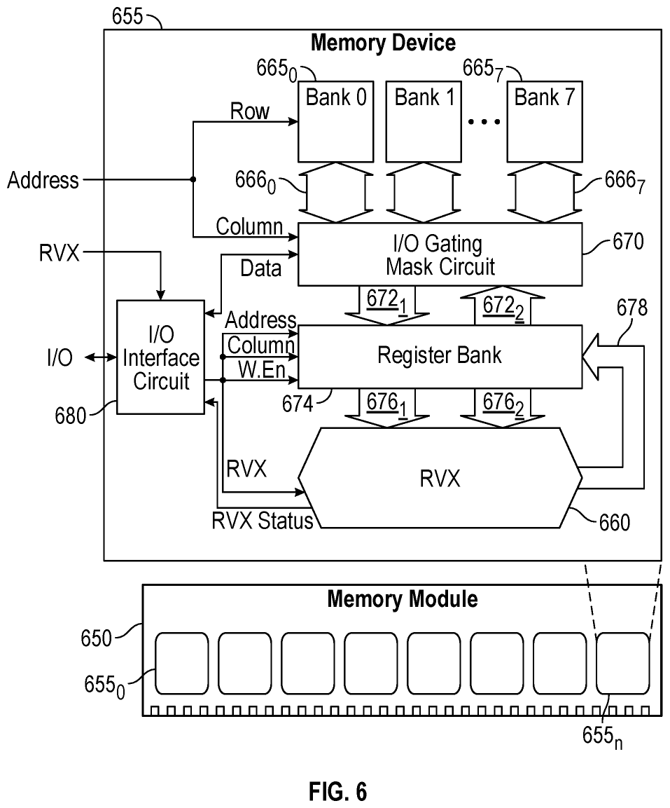

Referring now to FIG. 6, shown is a block diagram of a memory device in accordance with an embodiment. In the high level shown in FIG. 6, a memory 650, which may correspond to memory 550 of FIG. 5, is shown having a plurality of individual memory devices 655₀-655ₙ. In some embodiments, memory 650 may be implemented as a memory module, e.g., a dual inline memory module (DIMM). In other cases, memory 650 may be implemented on a single semiconductor die with, e.g., processor 510, where memory 650 may be implemented on one or more layers of a semiconductor die below processor core 510. Or memory 650 may be adapted on one semiconductor die and stacked on another semiconductor die on which core 510 is adapted.

FIG. 6 further illustrates an implementation of a given memory device within memory 650. As shown, memory device 655 includes a plurality of banks 665₀-665₇. Each bank may include a plurality of rows to store data. In one or more embodiments, each bank 665 may have a width between approximately 1 and 256 bytes. In one or more embodiments, adjacent banks may be differently oriented such that some banks can store row data (e.g., in an X-axis orientation) and other banks can store column data with the same orientation to improve access times. As seen, banks 665 may be accessed via row information obtained from an incoming address. In turn, column information of the address may be provided to input/output (I/O) gating mask circuit 670, coupled to banks 665 via a plurality of interconnects 666₀-666₇. Based on the column information, I/O gating mask circuit 670 may output data via interconnects 672_{1,2} to a register bank 674, which may be used for temporary storage. Data input or output from memory device 655 may be communicated to I/O interface circuit 680 and with I/O gating mask circuit 670. As further shown, column and write enable signaling to register bank 674 may be received from I/O interface circuit 680.

Still with reference to FIG. 6, register bank 674 couples via interconnects 676_{1,2} and 678 with RVX 660. In various embodiments, RVX 660 may be implemented on or more CMOS layers adapted below layers having banks 665 and the other memory circuitry as a multi-stage coarse-grained reconfigurable vector processing array. To provide for reconfigurable control of RVX 660, incoming RVX configuration information and RVX instructions may be received in I/O interface circuit 680 and provided to RVX 660. Depending upon the configuration information, RVX 660, e.g., via an internal configuration controller (which may be implemented as a finite state machine) may dynamically configure circuitry within RVX 660.

In one or more embodiments, incoming configuration information may be stored in a first bank 665 as a switch matrix. Then to configure RVX 660, individual bits of this configuration information may be sent via corresponding bitlines to switch circuitry (e.g., formed of pass gates, inverters or so forth) within RVX 660 to couple or maintain independently individual functional units. In this way, this configuration information may be stored as electric fuses to dynamically reconfigure RVX 660. Such dynamic reconfiguration stands in contrast to electronic fuses that are burned, fused or otherwise fixed on manufacture to statically fix a configuration.

Although embodiments are not limited in this regard, in different situations the configurability of RVX 660 may include control of a number of functional units to be used, their interconnection, as well as the number of read and write operations to occur for a given vector operation. Understand while shown at this high level in the embodiment of FIG. 6, many variations and alternatives are possible.

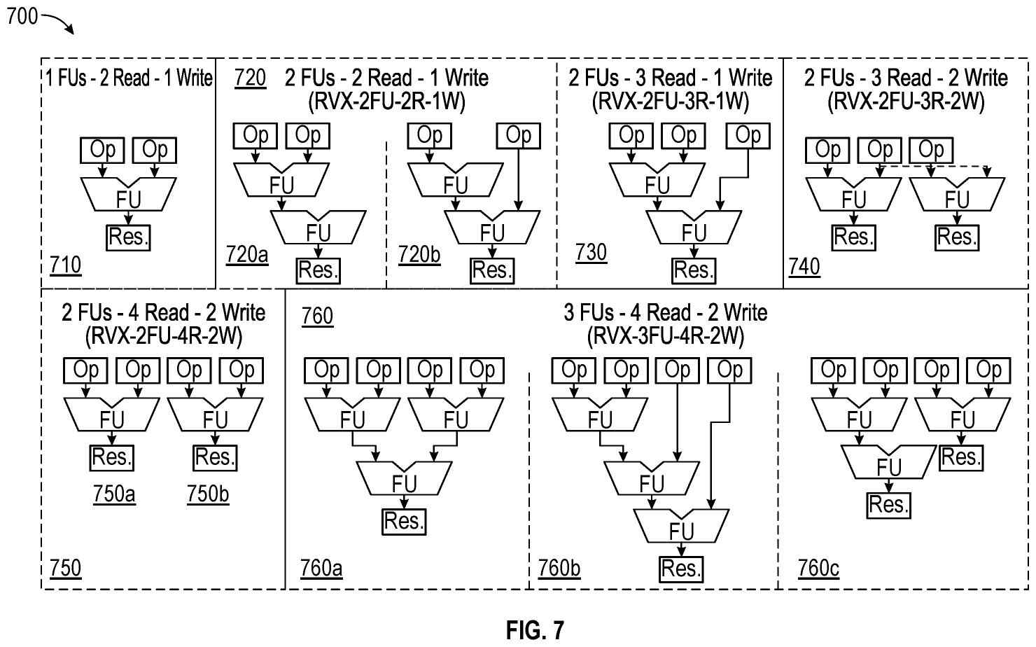

Referring now to FIG. 7, shown are schematic diagrams of possible configurations of a reconfigurable vector processing circuit (more generically a “reconfigurable processing circuit”) in accordance with an embodiment. As shown in FIG. 7, illustration 700 includes various configurations of a reconfigurable vector processing circuit such as RVX 660 of FIG. 6. At a high level, a reconfigurable processing circuit may include multiple functional units (FUs), each of which may be implemented as some type of computation circuit such as a vector adder, multiplier or so forth. Understand that each FU itself may be formed of multiple constituent adders or multipliers. The FUs may have a configurable width, e.g., ranging from 8 bits to 192 bits, in embodiments.

As shown in a first configuration 710, a reconfigurable processing circuit may be configured with one functional unit that receives a first source operand and a second source operand and generates a result operand. This baseline configuration may, in response to a single RVX instruction, receive two vector operands via two read operations, perform a vector operation, and provide a result operand via one write operation.

A second configuration 720 provides alternate embodiments 720a, 720b, each of which includes two functional units coupled in series. In configuration 720a, a first FU provides a result to a second FU that may perform another operation such as a convolving of data within word(s) to enable reuse of traces to generate a final result. Configuration 720b may be configured similarly, except with the provision of a second source operand to the second FU directly. In these configurations with two functional units, in response to a single RVX instruction, the FUs may perform a vector operation via two read operations, and provide a result operand via one write operation.

In a third configuration 730, a first FU provides a result to a second FU that may perform another operation with this result and another source operand to generate a final result. In this configuration, in response to a single RVX instruction, the FUs may perform a vector operation via three read operations and one write operation.

With regard to a fourth configuration 740, with two independent functional units, in response to a single RVX instruction, three source operands may be obtained via three read operations, and each FU generates an independent result that may be written back via two write operations.

With regard to a fifth configuration 750, with independent functional units, in response to a single RVX instruction, four source operands may be obtained via four read operations, and each FU generates an independent result that may be written back via two write operations.

Referring now to yet another configuration 760, a reconfigurable processing circuit may be configured with three functional units arranged in various configurations as shown in illustrations 760a-c. As seen, independent functional units may provide results to another functional unit, as shown in illustration 760a. Or three functional units can be coupled serially as shown in illustration 760b. Or as shown in illustration 760c, two functional units may be serially coupled and a third functional unit may be independent. In any of these configurations, the reconfigurable processing circuit, in response to a single RVX instruction, may be configured to perform four read operations to obtain four source operands and provide two results by way of two write operations.

While shown with these particular illustrations of configurations of a reconfigurable processing circuit, understand that many variations and alternatives are possible. For example, in other cases a reconfigurable processing circuit may include more than three functional units, and there may be different types of functional units present.

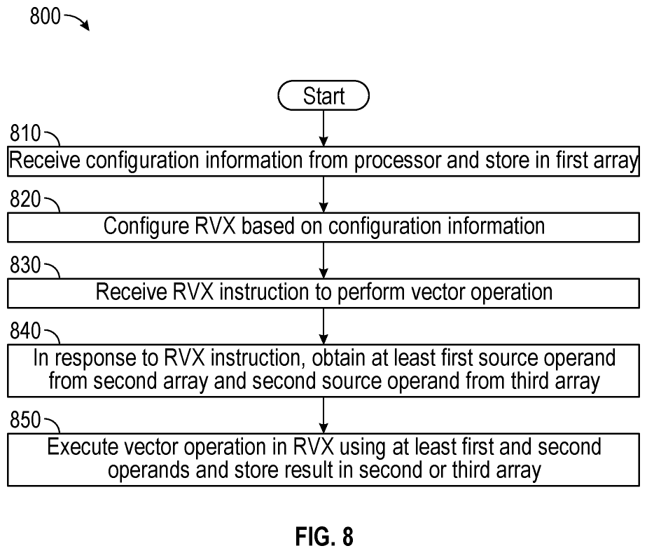

Referring now to FIG. 8, shown is a flow diagram of a method in accordance with an embodiment. As shown in FIG. 8, method 800 is a method for configuring and using a reconfigurable vector processor of a memory in accordance with an embodiment. As such, method 800 may be performed by hardware circuitry including configuration circuitry of the memory alone or in combination with firmware and/or software.

As illustrated, method 800 begins by receiving configuration information from a processor and storing it in a first array (block 810). This configuration information may include an identification of how the reconfigurable vector processor is to be configured, e.g., the number of functional units to be used, their interconnection (e.g., serially or independently or in parallel), the number of source operands and destination operands to be used for a given vector operation, and so forth. Note that this first array may be implemented as a switch matrix to store this configuration information for a reconfigurable vector processor with which the first array is associated (e.g., where the reconfigurable vector processor is local to this first array and adjacent arrays that may store vector data).

Next at block 820, the reconfigurable vector processor may be configured based on this configuration information. For example, certain control bits of the configuration information may be provided via bitlines from the first array to switch circuitry of the reconfigurable vector processor, which may couple FUs together (or maintain them separately) according to the configuration information. As such, this switch circuitry may be controlled by control bits of the configuration information to enable FUs of the reconfigurable vector processor to couple together serially or in parallel, or to maintain one or more FUs independently.

At this point, the reconfigurable vector processor is appropriately configured to execute RVX instructions. Thus still with reference to FIG. 8, at block 830 an RVX instruction may be received to perform a vector operation. This RVX instruction, which may be a single instruction of an ISA, may provide an indication of the type of vector operation (e.g., a vector multiplication) and an indication of source and destination operands. Next at block 840 in response to this instruction, the reconfigurable vector processor may obtain at least one first source operand from a second array and at least one second source operand from a third array. As discussed above, these arrays may be adjacent to the first array and may be locally associated with the reconfigurable vector processor. And the different arrays may be differently oriented to enable more efficient storage and access to row and column vector data. Finally at block 850, the reconfigurable vector processor may execute a vector operation using at least the first and second source operands. The result data may be stored back to one of the second or third arrays. In other cases, the result data may be provided to another destination indicated in the RVX instruction. Although shown at this high level in the embodiment of FIG. 8, many variations and alternatives are possible.

Packages in accordance with embodiments can be incorporated in many different system types, ranging from small portable devices such as a smartphone, laptop, tablet or so forth, to larger systems including client computers, server computers and datacenter systems.

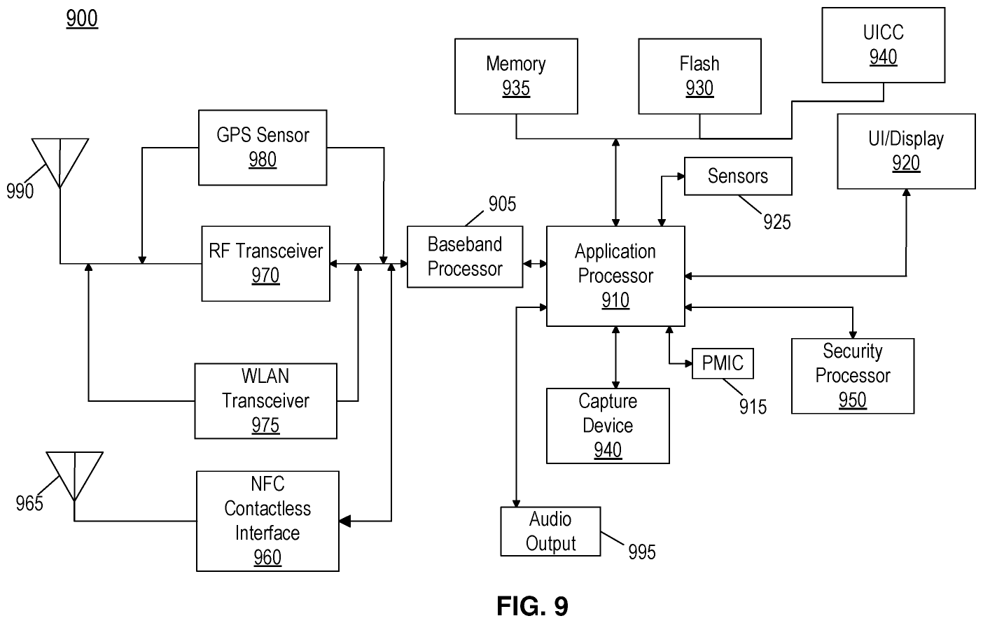

Referring now to FIG. 9, shown is a block diagram of an example system with which embodiments can be used. As seen, system 900 may be a smartphone or other wireless communicator. A baseband processor 905 is configured to perform various signal processing with regard to communication signals to be transmitted from or received by the system. In turn, baseband processor 905 is coupled to an application processor 910, which may be a main CPU of the system to execute an OS and other system software, in addition to user applications such as many well-known social media and multimedia apps. Application processor 910 may further be configured to perform a variety of other computing operations for the device.

In turn, application processor 910 can couple to a user interface/display 920, e.g., a touch screen display. In addition, application processor 910 may couple to a memory system including a non-volatile memory, namely a flash memory 930 and a system memory, namely a dynamic random access memory (DRAM) 935. In embodiments herein, a package may include multiple dies including at least processor 910 and DRAM 935, which may be stacked and configured as described herein. As further seen, application processor 910 further couples to a capture device 940 such as one or more image capture devices that can record video and/or still images.

Still referring to FIG. 9, a universal integrated circuit card (UICC) 940 comprising a subscriber identity module and possibly a secure storage and cryptoprocessor is also coupled to application processor 910. System 900 may further include a security processor 950 that may couple to application processor 910. A plurality of sensors 925 may couple to application processor 910 to enable input of a variety of sensed information such as accelerometer and other environmental information. An audio output device 995 may provide an interface to output sound, e.g., in the form of voice communications, played or streaming audio data and so forth.

As further illustrated, a near field communication (NFC) contactless interface 960 is provided that communicates in a NFC near field via an NFC antenna 965. While separate antennae are shown in FIG. 9, understand that in some implementations one antenna or a different set of antennae may be provided to enable various wireless functionality.

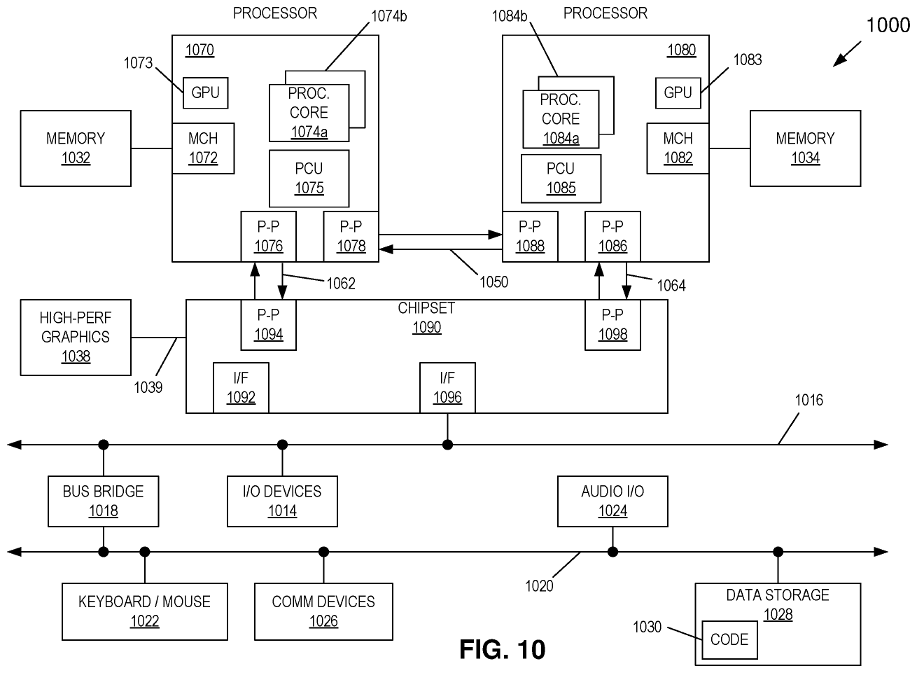

Embodiments may be implemented in other system types such as client or server systems. Referring now to FIG. 10, shown is a block diagram of a system in accordance with another embodiment. As shown in FIG. 10, multiprocessor system 1000 is a point-to-point interconnect system, and includes a first processor 1070 and a second processor 1080 coupled via a point-to-point interconnect 1050. As shown in FIG. 10, each of processors 1070 and 1080 may be multicore processors, including first and second processor cores (i.e., processors 1074a and 1074b and processor cores 1084a and 1084b), although potentially many more cores may be present in the processors. In addition, each of processors 1070 and 1080 also may include a graphics processor unit (GPU) 1073, 1083 to perform graphics operations. Each of the processors can include a power control unit (PCU) 1075, 1085 to perform processor-based power management.

Still referring to FIG. 10, first processor 1070 further includes a memory controller hub (MCH) 1072 and point-to-point (P-P) interfaces 1076 and 1078. Similarly, second processor 1080 includes a MCH 1082 and P-P interfaces 1086 and 1088. As shown in FIG. 10, MCH's 1072 and 1082 couple the processors to respective memories, namely a memory 1032 and a memory 1034, which may be portions of system memory (e.g., DRAM) locally attached to the respective processors. In embodiments herein, one or more packages may include multiple dies including at least processor 1070 and memory 1032 (e.g.), which may be stacked and configured as described herein.

First processor 1070 and second processor 1080 may be coupled to a chipset 1090 via P-P interconnects 1016 and 1064, respectively. As shown in FIG. 10, chipset 1090 includes P-P interfaces 1094 and 1098. Furthermore, chipset 1090 includes an interface 1092 to couple chipset 1090 with a high performance graphics engine 1038, by a P-P interconnect 1039. In turn, chipset 1090 may be coupled to a first bus 1016 via an interface 1096. As shown in FIG. 10, various input/output (1/O) devices 1014 may be coupled to first bus 1016, along with a bus bridge 1018 which couples first bus 1016 to a second bus 1020. Various devices may be coupled to second bus 1020 including, for example, a keyboard/mouse 1022, communication devices 1026 and a data storage unit 1028 such as a disk drive or other mass storage device which may include code 1030, in one embodiment. Further, an audio I/O 1024 may be coupled to second bus 1020.

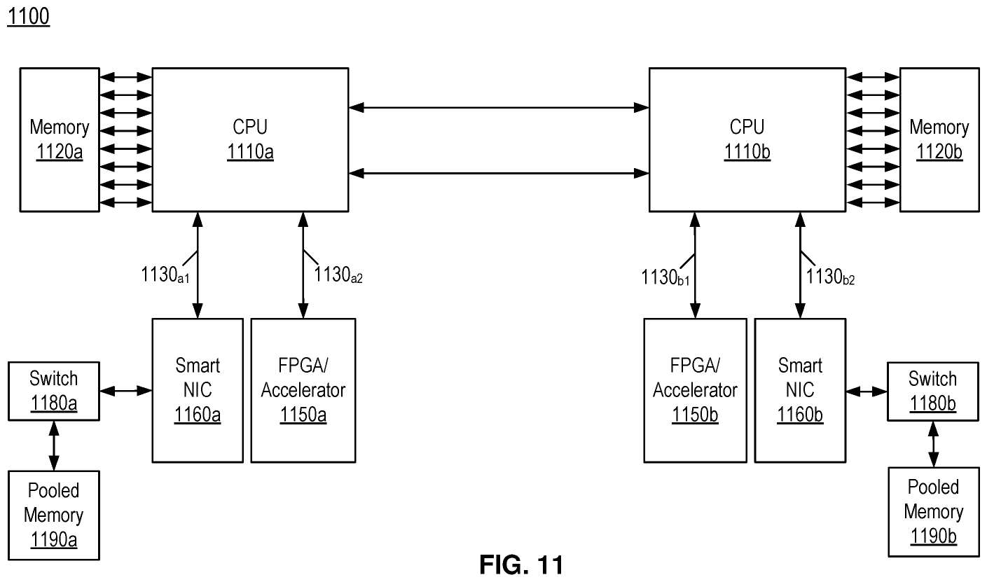

Referring now to FIG. 11, shown is a block diagram of a system 1100 in accordance with another embodiment. As shown in FIG. 11, system 1100 may be any type of computing device, and in one embodiment may be a datacenter system. In the embodiment of FIG. 11, system 1100 includes multiple CPUs 1110a,b that in turn couple to respective system memories 1120a,b which in embodiments may be implemented as double data rate (DDR) memory, persistent or other types of memory. Note that CPUs 1110 may couple together via an interconnect system 1115 implementing a coherency protocol. In embodiments herein, one or more packages may include multiple dies including at least CPU 1110 and system memory 1120 (e.g.), which may be stacked and configured as described herein.

To enable coherent accelerator devices and/or smart adapter devices to couple to CPUs 1110 by way of potentially multiple communication protocols, a plurality of interconnects 1130_{a1-b2} may be present.

In the embodiment shown, respective CPUs 1110 couple to corresponding field programmable gate arrays (FPGAs)/accelerator devices 1150a,b (which may include GPUs, in one embodiment). In addition CPUs 1110 also couple to smart NIC devices 1160a,b. In turn, smart NIC devices 1160a,b couple to switches 1180a,b that in turn couple to a pooled memory 1190a,b such as a persistent memory.

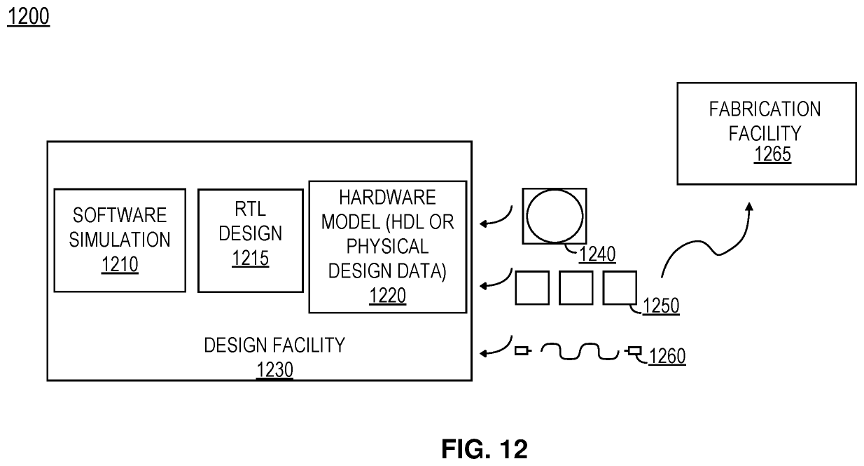

FIG. 12 is a block diagram illustrating an IP core development system 1200 that may be used to manufacture integrated circuit dies that can in turn be stacked to realize multi-die packages according to an embodiment. The IP core development system 1200 may be used to generate modular, re-usable designs that can be incorporated into a larger design or used to construct an entire integrated circuit (e.g., an SoC integrated circuit). A design facility 1230 can generate a software simulation 1210 of an IP core design in a high level programming language (e.g., C/C++). The software simulation 1210 can be used to design, test, and verify the behavior of the IP core. A register transfer level (RTL) design can then be created or synthesized from the simulation model. The RTL design 1215 is an abstraction of the behavior of the integrated circuit that models the flow of digital signals between hardware registers, including the associated logic performed using the modeled digital signals. In addition to an RTL design 1215, lower-level designs at the logic level or transistor level may also be created, designed, or synthesized. Thus, the particular details of the initial design and simulation may vary.

The RTL design 1215 or equivalent may be further synthesized by the design facility into a hardware model 1220, which may be in a hardware description language (HDL), or some other representation of physical design data. The HDL may be further simulated or tested to verify the IP core design. The IP core design can be stored for delivery to a third party fabrication facility 1265 using non-volatile memory 1240 (e.g., hard disk, flash memory, or any non-volatile storage medium). Alternately, the IP core design may be transmitted (e.g., via the Internet) over a wired connection 1250 or wireless connection 1260. The fabrication facility 1265 may then fabricate an integrated circuit that is based at least in part on the IP core design. The fabricated integrated circuit can be configured to be implemented in a package and perform operations in accordance with at least one embodiment described herein.

The following examples pertain to further embodiments.

In one example, an apparatus includes a die comprising a memory, the die comprising: one or more memory layers having a plurality of banks to store data; and at least one CMOS layer comprising at least one reconfigurable vector processor, the at least one reconfigurable vector processor to perform a vector computation on input vector data obtained from at least one bank of the plurality of banks and provide processed vector data to one or more of the plurality of banks.

In an example, the at least one reconfigurable vector processor comprises a multi-stage functional unit to perform the vector computation.

In an example, the apparatus further comprises a configuration circuit to configure the reconfigurable vector processor in response to configuration information received from a core coupled to the memory.

In an example, the plurality of banks comprises a plurality of arrays, where a first array is to store the configuration information, the first array being adjacent to a second array and a third array, where the second and third arrays are to store at least the input vector data.

In an example, the configuration circuit is to receive the configuration information from the first array and, based at least in part thereon, to configure the reconfigurable vector processor.

In an example, after the configuration of the reconfigurable vector processor, the reconfigurable vector processor is to perform a plurality of vector operations in response to a plurality of vector instructions received from the core.

In an example, the second array is to store column data and the third array is to store row data.

In an example, in a first configuration, the reconfigurable vector processor comprises: a first functional unit to receive a first source operand of the input vector data and a second source operand of the input vector data and generate a first result, where the first functional unit is to obtain the first source operand from the second array and obtain the second source operand from the third array.

In an example, the reconfigurable vector processor further comprises a second functional unit, where in the first configuration, the second functional unit is serially coupled to receive the first result from the first functional unit.

In an example, the reconfigurable vector processor further comprises a third functional unit coupled to at least one of the first functional unit or the second functional unit.

In an example, the configuration circuit, in response to second configuration information, is to cause the second functional unit to be independent of the first functional unit.

In another example, a method comprises: receiving, in a memory, configuration information for a reconfigurable vector processor of the memory; storing the configuration information in a first array of the memory; and configuring the reconfigurable vector processor based at least in part on the configuration information.

In an example, the method further comprises receiving, in the memory, a vector instruction of an instruction set architecture and performing a vector operation in the reconfigurable vector processor according to the vector instruction.

In an example, performing the vector operation comprises: obtaining a first source operand from a second array of the memory and obtaining a second source operand from a third array of the memory; executing the vector operation in the reconfigurable vector processor using the first and second source operands; and providing a result of the vector operation to be stored in one of the second array or the third array.

In an example, the method further comprises: receiving the vector instruction from a processor coupled to the memory; and after executing the vector operation in the reconfigurable vector processor, sending status information to the processor to indicate a completion of the vector operation, without providing the result to the processor.

In an example, configuring the reconfigurable vector processor comprises sending at least a portion of the configuration information from the first array to the reconfigurable vector processor via a plurality of bitlines, each of the plurality of bitlines to communicate a bit of the configuration information to at least one switch circuit of the reconfigurable vector processor.

In an example, the method further comprises: coupling, via a first switch circuit, a first functional unit of the reconfigurable vector processor to a second functional unit of the reconfigurable vector processor in response to a first bit of the configuration information communicated via a first bitline of the plurality of bitlines; and maintaining, via a second switch circuit, a third functional unit of the reconfigurable vector processor independent of the first functional unit and the second functional unit in response to a second bit of the configuration information communicated via a second bitline of the plurality of bitlines.

In another example, a computer readable medium including instructions is to perform the method of any of the above examples.

In a further example, a computer readable medium including data is to be used by at least one machine to fabricate at least one integrated circuit to perform the method of any one of the above examples.

In a still further example, an apparatus comprises means for performing the method of any one of the above examples.

In another example, a system comprises: a processor comprising at least one core to execute instructions; and a memory coupled to the processor. The memory may include: a first memory bank to store configuration information; a second memory bank to store first vector data; a third memory bank to store second vector data; and a reconfigurable vector processor to perform a vector computation on the first vector data and the second vector data, and provide result vector data to at least one of the second memory bank and the third memory bank. The reconfigurable vector processor may include: a first functional unit to perform a first vector operation using at least one of the first vector data or the second vector data; and a second functional unit to perform another vector operation, where: in a first configuration, the second functional unit is coupled to the first functional unit; and in a second configuration, the second functional unit is independent of the first functional unit.

In an example, the processor is to send first configuration information to the memory, and in response to the first configuration information the memory is to dynamically configure the reconfigurable vector processor to have the first configuration.

In an example, the processor is to send a first vector instruction of an instruction set architecture to the memory, and in response to the first vector instruction, the reconfigurable vector processor is to perform the vector computation, provide the result vector data to the at least one of the second memory bank and the third memory bank, and send a status message to the processor to inform the processor regarding completion of the first vector instruction.

In another example, an apparatus comprises: means for receiving configuration information for reconfigurable vector processing means of a memory; means for storing the configuration information in first array means of the memory; and means for configuring the reconfigurable vector processing means based at least in part on the configuration information.

In an example, the apparatus further comprises means for receiving a vector instruction of an instruction set architecture and means for performing a vector operation in the reconfigurable vector processing means according to the vector instruction.

In an example, the apparatus further comprises: means for obtaining a first source operand from second array means of the memory and means for obtaining a second source operand from third array means of the memory; means for executing the vector operation in the reconfigurable vector processing means using the first and second source operands; and means for storing a result of the vector operation in one of the second array means or the third array means.

In an example, the method further comprises: means for receiving the vector instruction from processing means coupled to the memory; and means for sending status information to the processing means to indicate a completion of the vector operation, without providing the result to the processing means.

Understand that various combinations of the above examples are possible.

Note that the terms “circuit” and “circuitry” are used interchangeably herein. As used herein, these terms and the term “logic” are used to refer to alone or in any combination, analog circuitry, digital circuitry, hard wired circuitry, programmable circuitry, processor circuitry, microcontroller circuitry, hardware logic circuitry, state machine circuitry and/or any other type of physical hardware component. Embodiments may be used in many different types of systems. For example, in one embodiment a communication device can be arranged to perform the various methods and techniques described herein. Of course, the scope of the present invention is not limited to a communication device, and instead other embodiments can be directed to other types of apparatus for processing instructions, or one or more machine readable media including instructions that in response to being executed on a computing device, cause the device to carry out one or more of the methods and techniques described herein.

Embodiments may be implemented in code and may be stored on a non-transitory storage medium having stored thereon instructions which can be used to program a system to perform the instructions. Embodiments also may be implemented in data and may be stored on a non-transitory storage medium, which if used by at least one machine, causes the at least one machine to fabricate at least one integrated circuit to perform one or more operations. Still further embodiments may be implemented in a computer readable storage medium including information that, when manufactured into a SOC or other processor, is to configure the SOC or other processor to perform one or more operations. The storage medium may include, but is not limited to, any type of disk including floppy disks, optical disks, solid state drives (SSDs), compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), magnetic or optical cards, or any other type of media suitable for storing electronic instructions.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
a die comprising a memory, the die comprising:
one or more memory layers having a plurality of banks to store data; and
at least one complementary metal oxide semiconductor (CMOS) layer comprising at least one reconfigurable vector processor, the at least one reconfigurable vector processor to perform a vector computation on input vector data obtained from at least one bank of the plurality of banks and provide processed vector data to one or more banks of the plurality of banks.

2. The apparatus of claim 1, wherein the at least one reconfigurable vector processor comprises a multi-stage functional unit to perform the vector computation.

3. The apparatus of claim 1, further comprising a configuration circuit to configure the reconfigurable vector processor in response to configuration information received from a core coupled to the memory.

4. The apparatus of claim 3, wherein the plurality of banks comprises a plurality of arrays, wherein a first array is to store the configuration information, the first array being adjacent to a second array and a third array, wherein the second and third arrays are to store at least the input vector data.

5. The apparatus of claim 4, wherein the configuration circuit is to receive the configuration information from the first array and, based at least in part thereon, to configure the reconfigurable vector processor.

6. The apparatus of claim 5, wherein after the configuration of the reconfigurable vector processor, the reconfigurable vector processor is to perform a plurality of vector operations in response to a plurality of vector instructions received from the core.

7. The apparatus of claim 5, wherein the second array is to store column data and the third array is to store row data.

8. The apparatus of claim 4, wherein in a first configuration, the reconfigurable vector processor comprises:
a first functional unit to receive a first source operand of the input vector data and a second source operand of the input vector data and generate a first result, wherein the first functional unit is to obtain the first source operand from the second array and obtain the second source operand from the third array.

9. The apparatus of claim 8, wherein the reconfigurable vector processor further comprises a second functional unit, wherein in the first configuration, the second functional unit is serially coupled to receive the first result from the first functional unit.

10. The apparatus of claim 9, wherein the reconfigurable vector processor further comprises a third functional unit coupled to at least one of the first functional unit or the second functional unit.

11. The apparatus of claim of claim 9, wherein the configuration circuit, in response to second configuration information, is to cause the second functional unit to be independent of the first functional unit.

12. A method comprising:
receiving, in a memory, configuration information for a reconfigurable vector processor of the memory;
storing the configuration information in a first array of the memory; and
configuring the reconfigurable vector processor based at least in part on the configuration information.

13. The method of claim 12, further comprising receiving, in the memory, a vector instruction of an instruction set architecture and performing a vector operation in the reconfigurable vector processor according to the vector instruction.

14. The method of claim 13, wherein performing the vector operation comprises:
obtaining a first source operand from a second array of the memory and obtaining a second source operand from a third array of the memory;
executing the vector operation in the reconfigurable vector processor using the first and second source operands; and
providing a result of the vector operation to be stored in one of the second array or the third array.

15. The method of claim 14, further comprising:
receiving the vector instruction from a processor coupled to the memory; and
after executing the vector operation in the reconfigurable vector processor, sending status information to the processor to indicate a completion of the vector operation, without providing the result to the processor.

16. The method of claim 12, wherein configuring the reconfigurable vector processor comprises sending at least a portion of the configuration information from the first array to the reconfigurable vector processor via a plurality of bitlines, each of the plurality of bitlines to communicate a bit of the configuration information to at least one switch circuit of the reconfigurable vector processor.

17. The method of claim 16, further comprising:
coupling, via a first switch circuit, a first functional unit of the reconfigurable vector processor to a second functional unit of the reconfigurable vector processor in response to a first bit of the configuration information communicated via a first bitline of the plurality of bitlines; and
maintaining, via a second switch circuit, a third functional unit of the reconfigurable vector processor independent of the first functional unit and the second functional unit in response to a second bit of the configuration information communicated via a second bitline of the plurality of bitlines

18. A system comprising:
a processor comprising at least one core to execute instructions; and
a memory coupled to the processor, the memory comprising:
a first memory bank to store configuration information;
a second memory bank to store first vector data;
a third memory bank to store second vector data; and
a reconfigurable vector processor to perform a vector computation on the first vector data and the second vector data, and provide result vector data to at least one of the second memory bank and the third memory bank, the reconfigurable vector processor comprising:
a first functional unit to perform a first vector operation using at least one of the first vector data or the second vector data; and
a second functional unit to perform another vector operation, wherein:
in a first configuration, the second functional unit is coupled to the first functional unit; and
in a second configuration, the second functional unit is independent of the first functional unit.

19. The system of claim 18, wherein the processor is to send first configuration information to the memory, and in response to the first configuration information the memory is to dynamically configure the reconfigurable vector processor to have the first configuration.

20. The system of claim 19, wherein the processor is to send a first vector instruction of an instruction set architecture to the memory, and in response to the first vector instruction, the reconfigurable vector processor is to perform the vector computation, provide the result vector data to the at least one of the second memory bank and the third memory bank, and send a status message to the processor to inform the processor regarding completion of the first vector instruction.
